(19) United States
(12) Patent Application Publication
(10) Pub. No.: US 2011/0049569 A1
(43) Pub. Date: Mar. 3, 2011

(54) Semiconductor structure including a field modulation body and method for fabricating same

(75) Inventor: Zhi He, El Segundo, CA (US)

(73) Assignee: INTERNATIONAL RECTIFIER CORPORATION, EL SEGUNDO, CA (US)

(21) Appl. No.: 12/584,293

(22) Filed: Sep. 2, 2009

(51) Int. Cl. H01L 29/80; H01L 21/335

(52) U.S. Cl. 257/192; 438/424; 438/191; 257/E21.403; 257/E29.315

(57) ABSTRACT

According to one embodiment, a semiconductor structure including an equipotential field modulation body comprises a trench surrounding an active region of a group III-V power device fabricated in the semiconductor structure, and the equipotential field modulation body formed in the trench and extending over a portion of the active region. The equipotential field modulation body is electrically coupled to a terminal of the group III-V power device. In one embodiment, a method for fabricating a semiconductor structure including an equipotential field modulation body comprises fabricating a trench surrounding an active region of the semiconductor structure, forming the equipotential field modulation body in the trench, the equipotential field modulation body extending over a portion of the active region, and electrically coupling the equipotential field modulation body to a terminal of a group III-V power device fabricated in the active region.

### BACKGROUND OF THE INVENTION

### Definition

In the present application, “group III-V semiconductor” refers to a compound semiconductor that includes at least one group III element and at least one group V element, such as, but not limited to, gallium nitride (GaN), gallium arsenide (GaAs), aluminum gallium arsenide (AlGaAs), indium gallium nitride (InGaN) and the like. Analogously, “III-nitride semiconductor” refers to a compound semiconductor that includes nitrogen and at least one group III element, such as, but not limited to, GaN, AlGaN, InN, AlN, InGaN, InAlGaN and the like.

### FIELD OF THE INVENTION

The present invention is generally in the field of semiconductors. More specifically, the present invention is in the field of fabrication of semiconductor devices utilized in high power applications.

### BACKGROUND ART

Power transistors and other power semiconductor devices are now in wide use in a variety of electronic devices and systems, and that trend promises to continue. Examples of such electronic devices and systems are semiconductor based switching and amplification devices employed in wireless communications, such as W-CDMA (wideband code division multiple access) base stations, as well as numerous other consumer and industrial applications.

Group III-V power semiconductor devices such as the heterostructure field effect transistor, or HFET, are particularly favored for some of these applications because of their high switching speeds and exceptional power handling capabilities. A typical HFET can be a lateral device, having gate, source, and drain, contacts arranged above a semiconductor heterojunction forming the active region of the device. In practice, the performance of an HFET or other power device depends in part on how effectively the large electrical fields generated across portions of the active region are managed. For example, where such fields are terminated abruptly, such as at the interface between the active region and an isolation structure surrounding the device, a phenomenon known as field crowding can occur, which may cause a reduction in the breakdown voltage and, thus, premature failure of the power device.

Unfortunately, conventional approaches to HFET fabrication have failed to adequately address the problem of field crowding near the active region boundary. In addition, those conventional approaches typically produce distributed regions of high and low electrical potential across the semiconductor structure supporting the HFET, making field confinement more challenging.

Thus, there is a need to overcome the drawbacks and deficiencies in the art by providing a solution for modulating field strength so as to avoid field crowding near the boundary of a power device active region.

### SUMMARY OF THE INVENTION

Semiconductor structure including a field modulation body and method for fabricating same, substantially as shown in and/or described in connection with at least one of the figures, as set forth more completely in the claims.

### BRIEF DESCRIPTION OF THE DRAWINGS

FIG. 1 is a top view showing a conventional heterostructure field effect transistor (HFET) layout.

FIG. 2 is a top view of a semiconductor structure showing an HFET layout including a substantially equipotential field modulation body, according to one embodiment of the present invention.

FIG. 3 is a flowchart presenting a method for fabricating a semiconductor structure including a substantially equipotential field modulation body, according to one embodiment of the present invention.

FIG. 4A shows a cross-sectional view of the semiconductor structure of FIG. 2 along either orientation of direction 4-4 at an early fabrication stage, according to one embodiment of the present invention.

FIG. 4B shows a cross-sectional view of the semiconductor structure of FIG. 2 along either orientation of direction 4-4 at an intermediate fabrication stage, according to one embodiment of the present invention.

FIG. 4C shows a cross-sectional view of the semiconductor structure of FIG. 2 along either orientation of direction 4-4 at an intermediate fabrication stage, according to one embodiment of the present invention.

FIG. 4D shows a cross-sectional view of the semiconductor structure of FIG. 2 along either orientation of direction 4-4 at an intermediate fabrication stage, according to one embodiment of the present invention.

### DETAILED DESCRIPTION OF THE INVENTION

The present invention is directed to a semiconductor structure including a field modulation body and method for fabricating same. Although the invention is described with respect to specific embodiments, the principles of the invention, as defined by the claims appended herein, can obviously be applied beyond the specifically described embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely example embodiments of the invention. To maintain brevity, other embodiments of the invention, which use the principles of the present invention, are not specifically described in the present application and are not specifically illustrated by the present drawings. It should be borne in mind that, unless noted otherwise, like or corresponding elements among the figures may be indicated by like or corresponding reference numerals. Moreover, the drawings and illustrations in the present application are generally not to scale, and are not intended to correspond to actual relative dimensions.

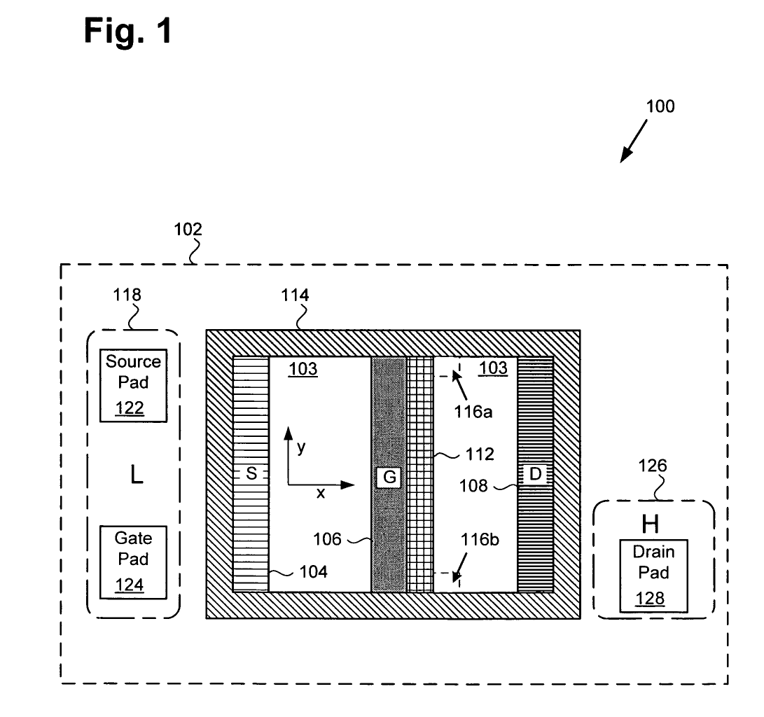

FIG. 1 is a top view showing a conventional group III-V semiconductor heterostructure field effect transistor (HFET) layout. Conventional structure 100, in FIG. 1, includes HFET 102 fabricated in active region 103 surrounded by isolation region 114. HFET 102 comprises source finger 104, gate finger 106, drain finger 108, and field plate 112 formed between gate finger 106 and drain finger 108. Also shown in FIG. 1 are source pad 122 and gate pad 124 of HFET 102, which produce low potential region 118 in structure 100, and drain pad 128 of HFET 102, producing high potential region 126 in structure 100. In addition, FIG. 1 shows field crowding zones 116a and 116b. It is noted that FIG. 1 is simplified for clarity. For example, although HFET 102 is shown to comprise a single active cell, a typical HFET would have multiple connected cells and thus several iterations of source finger 104, gate finger 106, and drain finger 108, formed in active region 103.

Group III-V semiconductor HFETs, as well as other group III-V semiconductor power devices, are designed to operate under large applied voltages and to generate large electrical fields. For example, typical values for the potential difference between gate finger 106 and drain finger 108 can range from 30 to 3000 volts. Under those conditions, the electric field strength in active region 103 between gate finger 106 and drain finger 108 can reach an undesirably strong peak adjacent to gate finger 106. In order to limit the peak field strength in that area, as well as to graduate the field strength more evenly in the “x” direction adjacent to gate finger 106, conventional structure 100 utilizes field plate 112, as is known in the art.

However, as shown by FIG. 1, in conventional structure 100, source finger 104, gate finger 106, and drain finger 108 are abruptly terminated in the “y” direction by isolation region 114. That abrupt termination has consequences for the powerful electric field present in the vicinity of gate finger 106 and field plate 112. Although in the “x” direction, that field can transition smoothly across active region 103 to drain finger 108, such is not the case in the “y” direction. The abrupt termination of the field at the interface of active region 103 and isolation region 114 causes field crowding near that boundary. Where the strength of the field being crowded is particularly strong, such as in field crowding zones 116a and 116b, the concentrated electric field undesirably lowers the breakdown voltage of HFET 102.

Moreover, as further shown in FIG. 1, drain pad 128 is typically situated on an opposite side of active area 103 from source pad 122 and gate pad 124. Source pad 122 and gate pad 124 may carry a potential difference between them of approximately 20 volts, whereas, as previously mentioned, the potential difference between gate pad 124 and drain pad 128 may be as great as 3000 volts. Thus, the conventional layout shown in FIG. 1 disadvantageously results in low potential region 118 and high potential region 126 being located on opposite ends of structure 100. As a result, the conventional approach makes it difficult to predict the electrical potential at locations in and across structure 100, as well as making it challenging to contain the fields produced there.

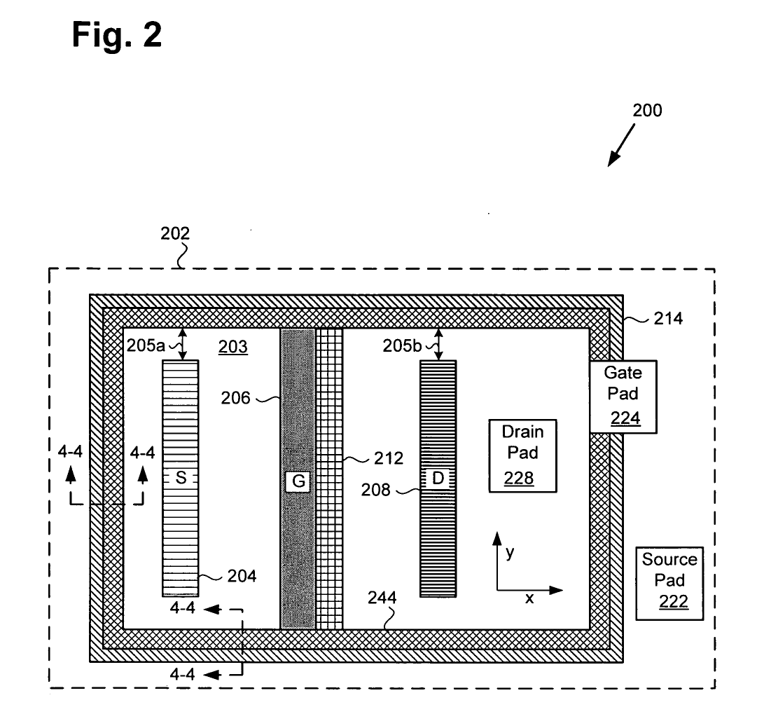

Turning to FIG. 2, FIG. 2 is a top view of a semiconductor structure showing an HFET layout including an equipotential or a substantially equipotential field modulation body (collectively referred to herein as “an equipotential field modulation body” for brevity), according to one embodiment of the present invention, that succeeds in overcoming the drawbacks and deficiencies of conventional structures. Structure 200, in FIG. 2, includes a group III-V power device, e.g., III-nitride HFET 202, fabricated in active region 203 surrounded by equipotential field modulation body 244 and isolation region 214. HFET 202 comprises source finger 204, gate finger 206, drain finger 208, and field plate 212 formed between gate finger 206 and drain finger 208. As shown in FIG. 2, gate finger 206 and field plate 212 extend to equipotential field modulation body 244. Also shown in FIG. 2 are source pad 222, gate pad 224 electrically coupled to equipotential field modulation body 244, and drain pad 228 formed within the perimeter determined by equipotential field modulation body 244. Notably absent from FIG. 2 are field crowding zones, such as field crowding zones 116a and 116b in FIG. 1, which plague conventional structures.

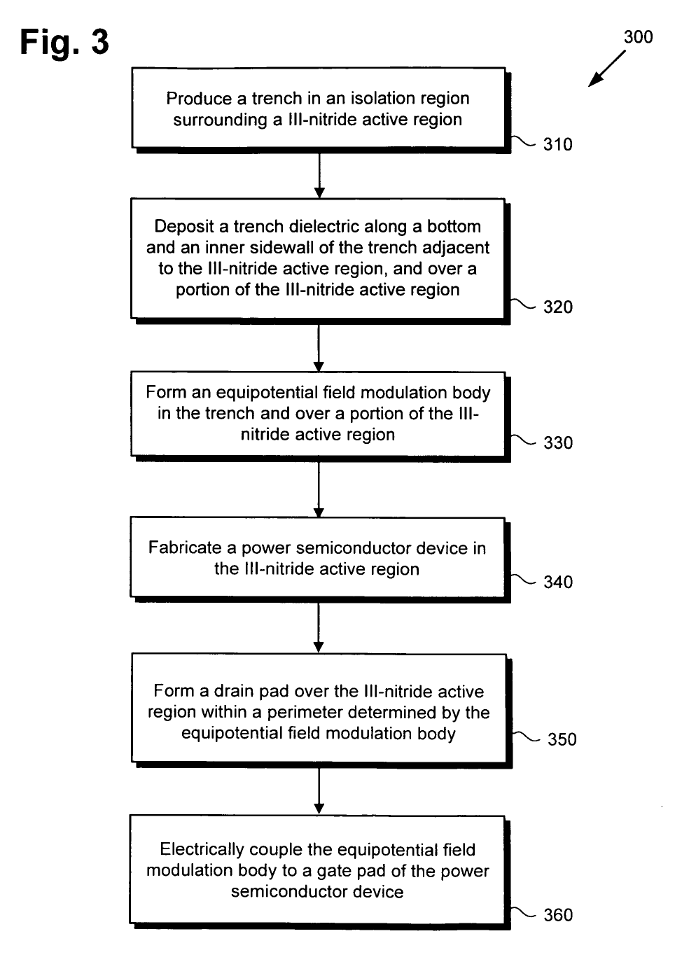

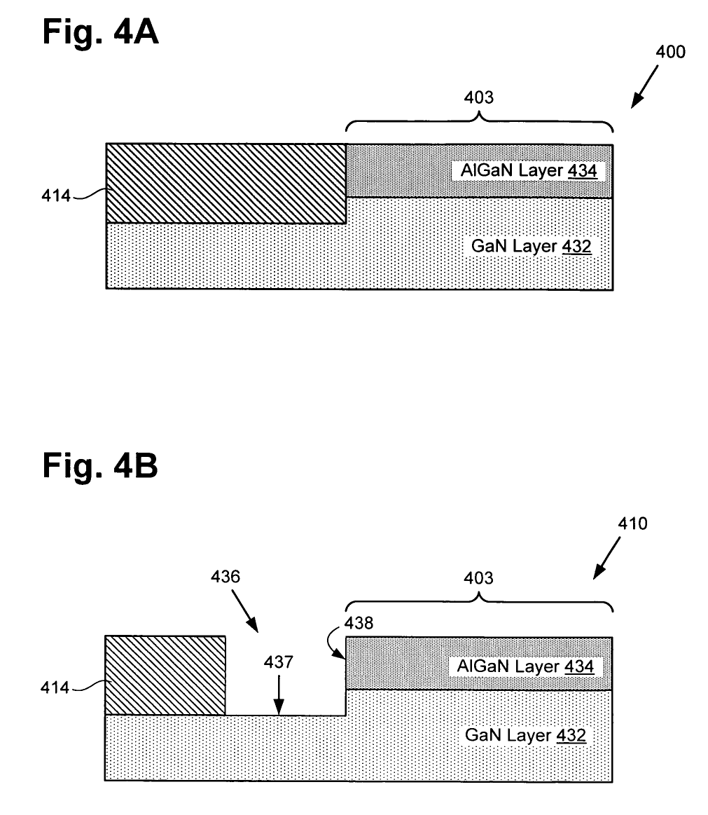

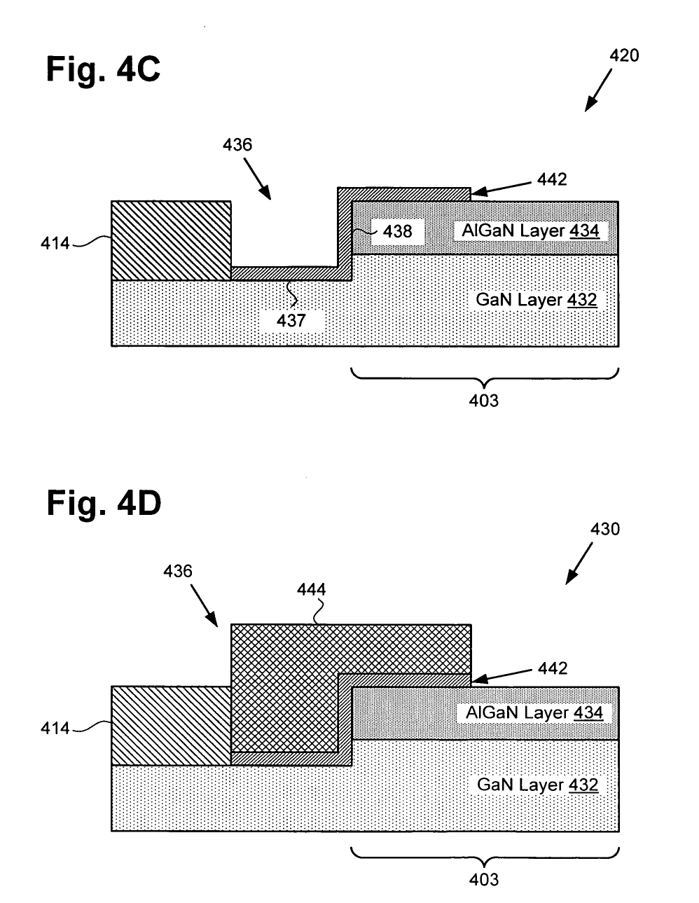

Some of the benefits and advantages accruing from structure 200 will be further described in combination with flowchart 300, in FIG. 3, and FIGS. 4A through 4D. Flowchart 300, in FIG. 3, presents one embodiment of a method for fabricating a semiconductor structure including an equipotential field modulation body. Certain details and features have been left out of flowchart 300 that are apparent to a person of ordinary skill in the art. For example, a step may comprise one or more substeps or may involve specialized equipment or materials, as known in the art. While steps 310 through 360 indicated in flowchart 300 are sufficient to describe one embodiment of the present invention, other embodiments of the invention may utilize steps different from those shown in flowchart 300, or may comprise more, or fewer, steps.

Referring now to FIG. 4A, structure 400 of FIG. 4A shows a cross-sectional view of the structure 200, in FIG. 2, along either orientation of direction 4-4 at an early fabrication stage. Structure 400 shows active region 403 corresponding to the heterojunction formed by the interface of gallium nitride (GaN) layer 432 and aluminum gallium nitride (AlGaN) layer 434. Also shown in FIG. 4A is isolation region 414 terminating active region 403. Isolation region 414 and active region 403 correspond respectively to isolation region 214 surrounding active region 203, in FIG. 2.

Although omitted from FIG. 4A for simplicity, structure 400 would typically further comprise a support substrate and transition body underlying GaN layer 432. Commonly utilized substrate materials for GaN include sapphire, silicon, and silicon carbide, for example. In addition, a typical implementation would include a transition body formed between the support substrate and GaN layer 432, comprising, for example, a plurality of layers mediating the lattice transition from the support substrate to GaN layer 432. Such a transition body may include, for example, an aluminum nitride (AlN) layer formed on the support substrate, followed by a series of layers comprising AlN and GaN, with each progressive layer comprising less aluminum and more gallium until a suitable transition to GaN layer 432 is achieved.

Moreover, although FIG. 4A corresponds to a portion of a semiconductor wafer in which active region 403 is formed, e.g., a single die formed on the wafer, the wafer as a whole may comprise numerous dies, each having an active region such as active region 403, and each terminated by an isolation region such as isolation region 414. Thus, the novel semiconductor structure including an equipotential field modulation body disclosed by the present application may be replicated to produce a plurality of such structures on a single wafer.

Referring also to FIGS. 4B, 4C, and 4D, structures 410, 420, and 430 show the result of performing, on structure 400, steps 310, 320, and 330 of flowchart 300 of FIG. 3, respectively. For example, structure 410 shows structure 400 following processing step 310, structure 420 shows structure 400 following processing step 320, and structure 430 shows structure 400 following processing step 330.

It is noted that the structures shown in FIGS. 2 and 4A through 4D are provided as specific implementations of the present inventive principles, and are shown with such specificity for the purposes of conceptual clarity. It should further be understood that particular details such as the materials characterized by FIGS. 2 and 4A through 4D, the semiconductor devices represented in those figures, and the techniques used to fabricate the various depicted features, are being provided as examples, and should not be interpreted as limitations. For example, although the embodiments shown in FIGS. 2 and 4A through 4D represent fabrication of a III-nitride semiconductor HFET in the form of a high electron mobility transistor (HEMT) implemented in GaN, in other embodiments a semiconductor structure including an equipotential field modulation body may comprise another type of group III-V power device, such as an N-channel or P-channel FET, or a diode, formed using GaN or any other suitable group III-V semiconductor materials, as described in the “Definition” section above.

Continuing with step 310 in FIG. 3 and structure 410 in FIG. 4B, step 310 of flowchart 300 comprises producing trench 436 in isolation region 414. As shown in FIG. 4B, trench 436 terminates the heterojunction formed at the interface of GaN layer 432 and AlGaN layer 434 by extending beyond AlGaN layer 343 and into GaN layer 432 of structure 410. Also shown in FIG. 4B are bottom 437 and inner sidewall 438 of trench 436. Trench 436 including bottom 437 and inner sidewall 438 may be fabricated along the entire length of isolation region 414. Because isolation region 414 and active region 403 correspond respectively to isolation region 214 surrounding active region 203, in FIG. 2, as previously explained, inner sidewall 438 of trench 436 surrounds and is adjacent to active region 403, according to the present embodiment. Trench 436 may be fabricated in any suitable manner, as known in the art, such as by an etch process.

Moving on to step 320 in FIG. 3 and structure 420 in FIG. 4C, step 320 of flowchart 300 comprises depositing trench dielectric 442 along bottom 437 and inner sidewall 438 of trench 436, and over a portion of active region 403. Trench dielectric 442 may comprise any suitable dielectric material, such as silicon nitride (Si₃N₄), AlN, aluminum oxide (Al₂O₃), or silicon oxide (SiO₂), for example. Although the present embodiment characterizes trench dielectric 442 as being deposited, in other embodiments trench dielectric 442 may be formed by other methods, such as by being grown, for example.

Referring to step 330 of FIG. 3 and structure 430 in FIG. 4D, step 330 of flowchart 300 comprises forming equipotential field modulation body 444 in trench 436 and over a portion of active layer 403, equipotential field modulation body 444 overlying trench dielectric 442. Equipotential field modulation body 444 is formed of an electrically conductive material, such as a metal, and corresponds to equipotential field modulation body 244, in FIG. 2. Thus, like equipotential field modulation body 244, which is shown to surround active region 203, equipotential field modulation body 444, in FIG. 4D, surrounds active region 403.

Continuing with step 340 of flowchart 300 and referring now to structure 200, in FIG. 2, step 340 of flowchart 300 comprises fabricating III-nitride HFET 202 in active region 203. FIG. 2 shows a representative HFET cell including source finger 204, gate finger 206 in combination with field plate 212, and drain finger 208. As shown in FIG. 2, unlike conventional structure 100, in FIG. 1, which abruptly terminates source finger 104, gate finger 106, and drain finger 108, by isolation region 114, structure 200 includes spacing between the boundary of active region 203 and the ends of source finger 204 and drain finger 208, and provides equipotential field modulation body 244 to mediate the transition from the ends of gate finger 206 and field plate 212 to isolation region 214. Thus, spacings such as 205a and 205b, for example, distance respective source finger 204 and drain finger 208 from equipotential field modulation body 244 in the “y” direction, while equipotential field modulation body 244 prevents occurrence of field crowding at the ends of gate finger 206 and field plate 212 in the “y” direction.

Moving on to steps 350 and 360 of FIG. 3 while continuing to refer to structure 200, in FIG. 2, step 350 of flowchart 300 comprises forming drain pad 228 over active region 203 within the perimeter determined by equipotential field modulation body 244. In addition, source pad 222 and gate pad 224 may be formed. Then, step 360 comprises electrically coupling equipotential field modulation body 244 to a terminal of III-nitride HFET 202, such as by connection through gate pad 224, thus fixing equipotential field modulation body 244 at the gate potential. In another embodiment, in which, for example, structure 200 comprises a III-nitride power diode rather than III-nitride HFET 202, step 350 may correspond to forming a cathode pad within the perimeter determined by equipotential field modulation body 244, and coupling equipotential field modulation body 244 to the anode terminal of the power diode.

As can be appreciated from the foregoing discussion and examination of the embodiment shown by FIG. 2, the present application discloses a novel structure and method providing field modulation in both the “x” and “y” directions, while also providing effective field containment. For example, field modulation in the “x” direction can be provided by equipotential field modulation body 244 fixed at the gate potential, and field plate 212. By way of further example, field modulation in the “y” direction can be provided by equipotential field modulation body 244, and may be facilitated by the spacings between equipotential field modulation body 244 and the ends of source finger 204 and drain finger 208. Moreover, by situating a high potential device pad, such as drain pad 228 or a cathode contact pad of a power diode, within a perimeter determined by equipotential field modulation body 244 fixed at a low potential, such as by electrical coupling to gate pad 224 or an anode contact of a power diode, field containment may also be achieved, rendering the electrical potential in and across structure 200 more predictable.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention.

1. A semiconductor structure including a field modulation body, said semiconductor structure comprising:
a trench surrounding an active region of a group III-V power device fabricated in said semiconductor structure;
said field modulation body formed in said trench and extending over a portion of said active region;
said field modulation body being electrically coupled to a terminal of said group III-V power device.

2. The semiconductor structure of claim 1, wherein said trench is fabricated in an isolation region surrounding said active region of said group III-V power device.

3. The semiconductor structure of claim 1, further comprising a trench dielectric formed in said trench and extending over said portion of said active region, said field modulation body overlying said trench dielectric.

4. The semiconductor structure of claim 1, wherein said field modulation body comprises a metal.

5. The semiconductor structure of claim 1, wherein said group III-V power device comprises a III-nitride heterostructure field-effect transistor (HFET).

6. The semiconductor structure of claim 5, wherein said terminal of said group III-V power device to which said field modulation body is electrically coupled is a gate of said III-nitride HFET.

7. The semiconductor structure of claim 1, wherein said group III-V power device comprises a III-nitride diode.

8. The semiconductor structure of claim 7, wherein said terminal of said group III-V power device to which said field modulation body is electrically coupled is an anode of said III-nitride diode.

9. The semiconductor structure of claim 1, wherein a contact pad of another terminal of said group III-V power device is formed within a perimeter determined by said field modulation body.

10. The semiconductor structure of claim 9, wherein said contact pad is either an HFET drain contact or a diode cathode contact.

11. A method comprising:
fabricating a trench surrounding an active region of a semiconductor structure, said active region including a group III-V power device;
forming a field modulation body in said trench, said field modulation body extending over a portion of said active region; and
electrically coupling said field modulation body to a terminal of said group III-V power device.

12. The method of claim 11, wherein said trench is fabricated in an isolation region surrounding said active region.

13. The method of claim 11, further comprising forming a trench dielectric in said trench and extending over said portion of said active region, said field modulation body overlying said trench dielectric.

14. The method of claim 11, wherein said field modulation body comprises a metal.

15. The method of claim 11, wherein said group III-V power device comprises a III-nitride heterostructure field-effect transistor (HFET).

16. The method of claim 15, wherein said terminal of said group III-V power device to which said field modulation body is electrically coupled is a gate of said III-nitride HFET.

17. The method of claim 11, wherein said group III-V power device comprises a III-nitride diode.

18. The method of claim 17, wherein said terminal of said group III-V power device to which said field modulation body is electrically coupled is an anode of said III-nitride diode.

19. The method of claim 11, further comprising forming a contact pad of another terminal of said group III-V power device within a perimeter determined by said field modulation body.

20. The method of claim 19, wherein said contact pad is either an HFET drain contact or a diode cathode contact.
